(19) United States
(12) Patent Application Publication
(10) Pub. No.: US 2007/0164801 A1
(43) Pub. Date: Jul. 19, 2007

(54) Low hysteresis center offset comparator

(75) Inventors: Yi-Chen Chen, Hsinchu (TW); Kevin Hsiao, Hsinchu (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Holtek Semiconductor Inc., Hsinchu (TW)

(21) Appl. No.: 11/386,369

(22) Filed: Mar. 22, 2006

(30) Foreign Application Priority Data
Jan. 16, 2006 (TW) 095101651

(51) Int. Cl. H03K 3/00

(52) U.S. Cl. 327/205

(57) ABSTRACT

Disclosed is a low hysteresis center offset comparator, comprising a first switch device, a differential amplifier, a second switch device, a general comparator, a first inverter and a second inverter. By means of the components, a hysteresis window with the low hysteresis center offset may be formed with respect to the inventive comparator with a width of a half-portion thereof formed equal to that of the other half-portion thereof corresponding to an offset voltage inherent in the differential amplifier.

### FIELD OF THE INVENTION

The present invention relates to a comparator with hysteresis. More particularly, the present invention relates to a low hysteresis center offset comparator.

### BACKGROUND OF THE INVENTION

Comparator is an electronic component for signal comparison so that the level of a signal may be determined. In essence, there is a hysteresis region with the transfer curve of such kind of comparator and there is a center line with the hysteresis region. Generally, the center line of the hysteresis region may shift in ordinary situations. In some cases, the application circuit with such comparator would require the comparator to have a fixed center line with its transfer curve, i.e. the center line is located at or near a line where two inputs of the comparator are equal to each other, so that the specific function thereof may be maintained. Constant current charging circuit is one example among such application circuits.

Referring to FIGS. 1A and 1B, a circuit diagram and a schematic hysteresis region diagram of a general comparator with hysteresis are respectively shown therein. As shown, the circuit 10 has two operating voltages, VDD and VSS. A bias voltage BIAS is provided on a transistor Q1. Two inputs INN and INP are fed into the circuit 10 and an output OUTPUT is obtained from the circuit 10. With respect to the inputs INN, INP and the output OUTPUT, a transfer curve with a hysteresis region H is obtained. Seen from the transfer curve, the hysteresis region H is known to have two asymmetric halves, i.e. the two inputs INN and INP are equal to each other at a line rather than a center line of the hysteresis region H. Namely, only when one of the inputs INN and INP is greater than the other by a specific value or the other is smaller than the one by another specific value, will the output OUTPUT transitions.

Therefore, there is a need to provide a low hysteresis center offset comparator so that a specific application circuit may not function abnormally due to the non-ideal comparator.

After a long intensive series of experiments and researches, the inventors finally sets forth such a low hysteresis center offset comparator, which may effectively overcome the demerits existing in the prior art.

### SUMMARY OF THE INVENTION

It is, therefore, an object of the present invention to provide a low hysteresis center offset comparator to meet the requirement of a specific application circuit.

In accordance with the present invention, the low hysteresis center offset comparator comprises a first switch device, a differential amplifier having a non-inverting terminal and an inverting terminal, wherein the non-inverting terminal has an offset voltage and receives one of a non-inverting input signal and an inverting input signal via the first switch device and the inverting terminal receives one of the inverting input signal and the non-inverting input signal via the first switch device to output a differential non-inverting output signal and a differential inverting output signal, a second switch device, a comparator having a non-inverting terminal and an inverting terminal, wherein the non-inverting terminal receives one of the differential non-inverting output signal and the differential inverting output signal via the second switch device and the inverting terminal receives one of the differential inverting output signal and the non-inverting output signal to output a transitional output signal, a first inverter receiving and inverting the transitional output signal to generate a first control signal; and a second inverter receiving and inverting the first control signal to generate a second control signal as an output signal, wherein the first and second control signals jointly control the first and second switch devices so as to make the output signal have a minimum hysteresis center offset.

In a preferred embodiment, the first switch device has a first to fourth switches and the second switch device has a fifth to eighth switches, the first, third, fifth and seventh switches being controlled by the first control signal, while the second, fourth, sixth and eighth switches being controlled by the second control signal.

With use of the low hysteresis center offset comparator, the minimum hysteresis center offset is assured and thus the application circuit may be exempted from an effect caused by the hysteresis center offset.

Other objects, advantages and efficacies of the present invention will be described in detail below taken from the preferred embodiments with reference to the accompanying drawings.

### BRIEF DESCRIPTION OF THE DRAWINGS

The foregoing summary, as well as the following detailed description of the preferred embodiments, is better understood when read in conjunction with the appended drawings. It is understood, however, that the invention is not limited to the specific methods and disclosed or illustrated. In the drawings:

FIG. 1A is a circuit diagram of a general comparator with hysteresis;

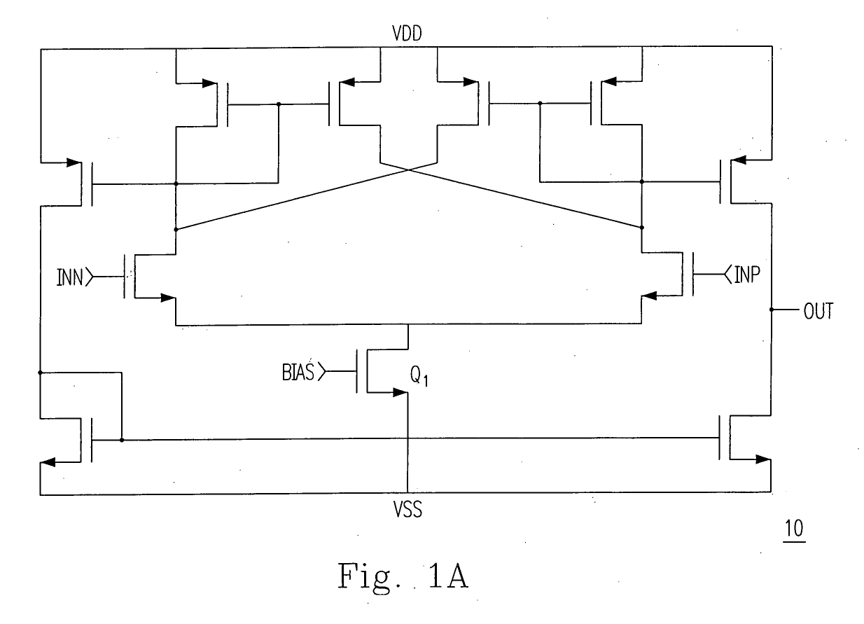

FIG. 1B is a schematic hysteresis region diagram of the general comparator with hysteresis;

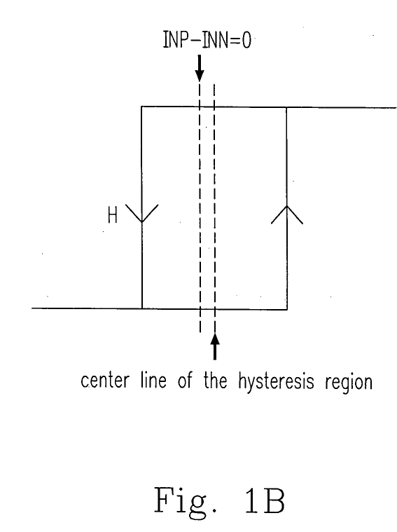

FIG. 2 is a schematic circuit diagram of a low hysteresis center offset comparator according to the present invention;

FIG. 3A is an implementation diagram of the circuit shown in FIG. 2;

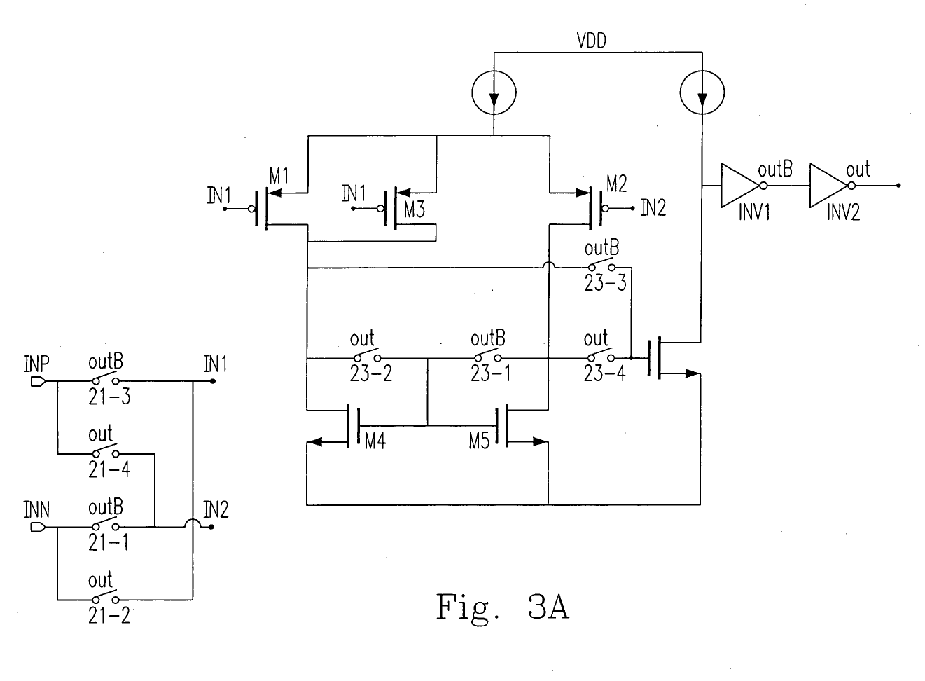

FIG. 3B is a schematic hysteresis region diagram obtained from the circuit shown in FIG. 2;

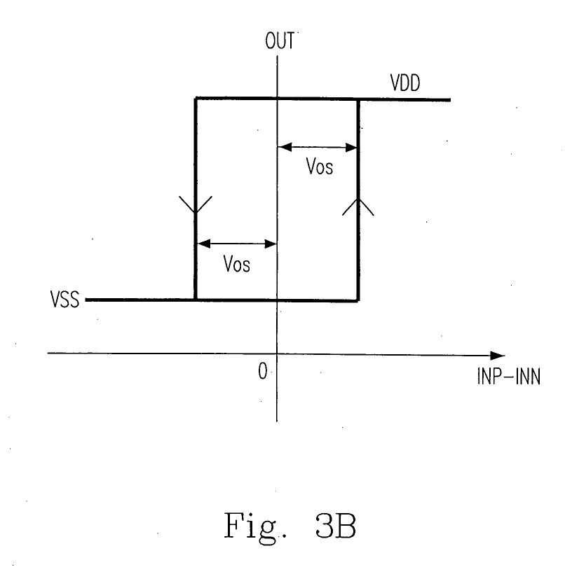

FIG. 4A is a circuit diagram of a constant current charging circuit with the low hysteresis center offset comparator shown in FIG. 2; and

FIG. 4B is a waveform diagram of a sense voltage of the constant current charging circuit shown in FIG. 4A.

### DETAILED DESCRIPTION OF THE PREFERRED EMBODIMENT

The present invention discloses a low hysteresis center offset comparator, which will be described through the preferred embodiment with reference to the appended drawings.

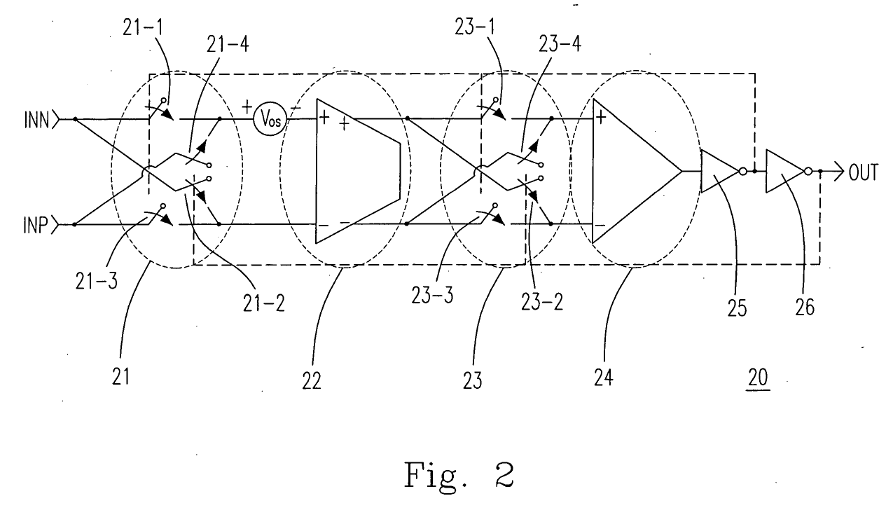

Referring to FIG. 2, a schematic circuit diagram of the low hysteresis center offset comparator of the present invention is shown therein. As shown, the low hysteresis center offset comparator 20 comprises a first switch device 21, a differential amplifier 22, a second switch device 23, a comparator 24, a first inverter 25 and a second inverter 26. The differential amplifier 22 has a non-inverting terminal and an inverting terminal and an offset voltage Vos exists at the non-inverting terminal thereof. An input signal INP is fed into the non-inverting terminal of the differential amplifier 22 via the first switch device 21 and the other input signal INN is fed into the inverting terminal of the differential amplifier 22 via the first switch device 21. Next, a differential non-inverting output signal and a differential inverting output signal are outputted from the differential amplifier 22. Then, the differential non-inverting and inverting output signals are inputted into the comparator 24 at a non-inverting terminal and an inverting terminal, respectively, via the second switch device 23, and a transitional output signal is outputted from the comparator 24. Thereafter, the transitional output signal is fed into the first inverter 25 and a first control signal is generated from the first inverter 25. Then, the first control signal is further fed into the second inverter 26 to generate a second control signal. The first and second control signals are jointly used to control the first and second switches to be on or close. Finally, the second control signal is outputted as a final output signal OUT.

In the above, the first switch device 21 includes a first, second, third and fourth switches 21-1, 21-2, 21-3, 21-4 and the second switch device 23 includes a fifth, sixth, seventh and an eighth switches 23-1, 23-2, 23-3, 23-4. In the first switch device 21, the first switch 21-1 receives a non-inverting input signal and connected to the non-inverting terminal of the differential amplifier 22. The second switch 21-2 receives the non-inverting input signal and connected to the inverting terminal of the differential amplifier 22. The third switch 21-3 receives the inverting input signal and connected to the inverting terminal of the differential amplifier 22. The fourth switch receives the inverting input signal and connected to the non-inverting terminal of the differential amplifier 22. In the second switch device 23, the fifth switch 23-1 receives the differential non-inverting output signal and connected to the non-inverting terminal of the comparator 24. The sixth switch 23-2 receives the differential non-inverting output signal and connected to the inverting terminal of the comparator 24. The seventh switch 23-3 receives the differential inverting output signal and connected to the inverting terminal of the comparator 24. The eighth switch 23-4 receives the differential inverting output signal and connected to the non-inverting terminal of the comparator 24. In operation, each of the first, third, fifth and seventh switches 21-1, 21-3, 23-1, 23-3 is controlled by the first control signal to be on and close, and each of the second, fourth, sixth and eighth switches 21-2, 21-4, 23-2, 23-4 is controlled by the second control signal to be on and close. In this manner, the hysteresis region of the final output signal has a minimum hysteresis center offset.

More specifically, when INP<INN−Vos, the first inverter 25 has a high level output, enabling the first, third, fifth and seventh switches 21-1, 21-3, 23-1 and 23-3 to be on (short circuit). Meanwhile, the second inverter 26 has a low level output, enabling the second, fourth, sixth and eighth switches 21-2, 21-4, 23-2 and 23-4 to be off (open circuit). Since there is the offset voltage Vos at the non-inverting terminal of the differential amplifier 22, the output of the comparator 24 may transition to high only when the input signal INP is increased to INP=INN+Vos. When INP>INN+Vos, the first inverter 25 has a low level output, enabling the first, third, fifth and seventh switches 21-1, 21-3, 23-1 and 23-3 to be off (open circuit). Meanwhile, the second inverter 26 has a high level output, enabling the second, fourth, sixth and eighth switches 21-2, 21-4, 23-2 and 23-4 to be on (close circuit). Since there is the offset voltage Vos at the non-inverting terminal of the differential amplifier 22, the output of the comparator 24 may transition to low only when the input signal INP is decreased to INP=INN−Vos. In this manner, the hysteresis region of a transfer curve of the low hysteresis center offset comparator of the present invention may indeed be maintained minimum.

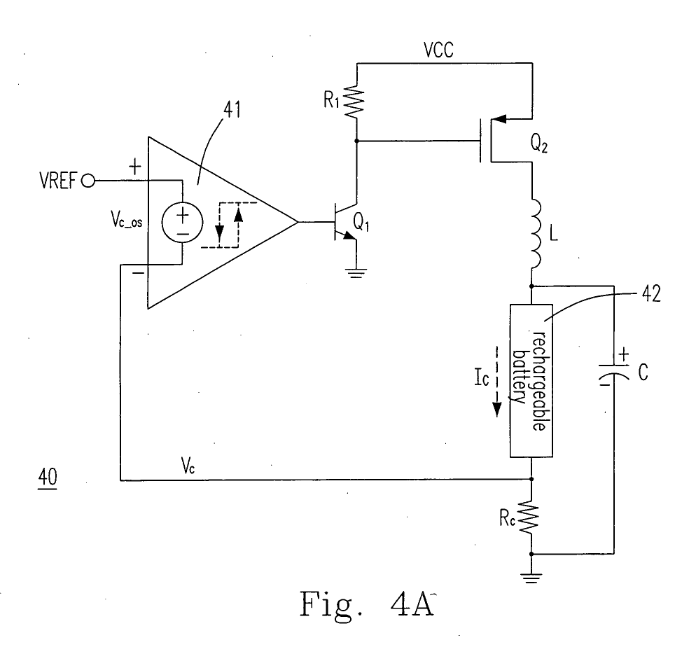

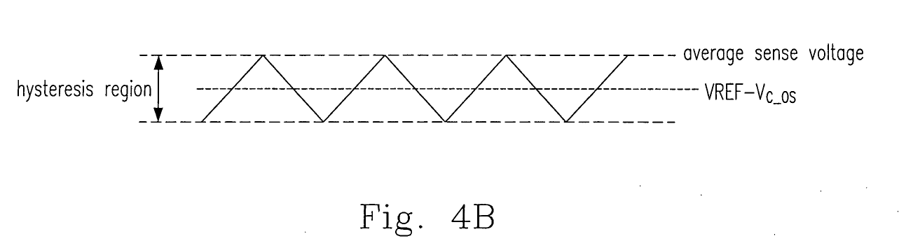

Referring to FIG. 4A, a circuit diagram of a constant current charging circuit with the low hysteresis center offset comparator shown in FIG. 2 is depicted therein. As shown, the constant current charging circuit 40 comprises the low hysteresis center offset comparator of the present invention 41, a bipolar junction transistor (BJT) Q1, a resistor RI, a field effect transistor (FET) Q2, an inductance L, a capacitor C, a resistor Rc and a rechargeable battery 42. With supply of an operating voltage VCC, a positive input signal Vref is inputted to the comparator 41 at a non-inverting input terminal and the FET Q2 is supplied with a specific working voltage VCC, causing the rechargeable battery 42 to be charged, with an average charging current Ic=Vc/Rc=(Vref−Vc_os)/Rc, wherein Vc is a sense voltage reflecting the charging current Ic and Vc_os represents the hysteresis center offset. Since the constant current charging circuit 40 is expected to charge the battery 42 with the charging current Vref/Rc=Ic, an average current error—Vc_os/Rc had better be maintained minimum, i.e., the offset voltage Vc_os had better be maintained minimum. Referring next to FIG. 4B, a waveform diagram of the sense voltage Vc of the constant current charging circuit shown in FIG. 4A is depicted therein. As shown, the sense voltage Vc fluctuates within the hysteresis region of the low hysteresis center offset comparator.

With use of the low hysteresis center offset comparator, the minimum hysteresis center offset is assured and thus the application circuit may be exempted from an effect caused by the hysteresis center offset.

While the invention has been described in terms of what is presently considered to be the most practical and preferred embodiments, it is to be understood that the invention needs not be limited to the disclosed embodiments. For example, although the low hysteresis center offset comparator is described with respect to the voltage comparator with hysteresis, the present invention also contemplates a current comparator with hysteresis, which has the similar operation and principle as compared to the voltage comparator with hysteresis. In addition, the offset voltage existing at the non-inverting terminal of the differential amplifier may be that inherent in or applied externally to the differential amplifier, or even any equivalent to a difference between the non-inverting and inverting terminals. Therefore, it is intended to cover various modifications and similar arrangements included within the spirit and scope of the appended claims, which are to be accorded with the broadest interpretation so as to encompass all such modifications and similar structures.

What is claimed is:

1. A voltage comparator with a hysteresis, comprising:
a first switch device;
a differential amplifier having a non-inverting terminal and an inverting terminal, wherein the non-inverting terminal has an offset voltage and receives one of a non-inverting input signal and an inverting input signal via the first switch device and the inverting terminal receives one of the inverting input signal and the non-inverting input signal via the first switch device to output a differential non-inverting output signal and a differential inverting output signal;
a second switch device;
a comparator having a non-inverting terminal and an inverting terminal, wherein the non-inverting terminal receives one of the differential non-inverting output signal and the differential inverting output signal via the second switch device and the inverting terminal receives one of the differential inverting output signal and the non-inverting output signal to output a transitional output signal;
a first inverter receiving and inverting the transitional output signal to generate a first control signal; and
a second inverter receiving and inverting the first control signal to generate a second control signal as an output signal,
wherein the first and second control signals jointly control the first and second switch devices so as to make the output signal have a minimum hysteresis center offset.

2. The voltage comparator according to claim 1, wherein the first switch device comprises:
a first switch receiving the non-inverting input signal and connected to the non-inverting terminal of the differential amplifier;
a second switch receiving the non-inverting input signal and connected to the inverting terminal of the differential amplifier;
a third switch receiving the inverting input signal and connected to the inverting terminal of the differential amplifier; and
a fourth switch receiving the inverting input signal and connected to the non-inverting terminal of the differential amplifier, and the second switch device comprises:
a fifth switch receiving the differential non-inverting output signal and connected to the non-inverting terminal of the comparator;
a sixth switch receiving the differential non-inverting output signal and connected to the inverting terminal of the comparator;
a seventh switch receiving the differential inverting output signal and connected to the inverting terminal of the comparator; and
an eighth switch receiving the differential inverting output signal and connected to the non-inverting terminal of the comparator,
wherein each of the first, third, fifth and seventh switches is controlled by the first control signal to be on and close, and each of the second, fourth, sixth and eighth switches is controlled by the second control signal to be on and close.

3. The voltage comparator according to claim 1, wherein the offset voltage is inherent in the differential amplifier.

4. The voltage comparator according to claim 1, wherein the offset voltage is externally applied to the differential amplifier.

5. A current comparator with a hysteresis, comprising:
a first switch device;
a differential amplifier having a non-inverting terminal and an inverting terminal, wherein the non-inverting terminal has an offset current and receives one of a non-inverting input signal and an inverting input signal via the first switch device and the inverting terminal receives one of the inverting input signal and the non-inverting input signal via the first switch device to output a differential non-inverting output signal and a differential inverting output signal;
a second switch device;
a comparator having a non-inverting terminal and an inverting terminal,
wherein the non-inverting terminal receives one of the differential non-inverting output signal and the differential inverting output signal via the second switch device and the inverting terminal receives one of the differential inverting output signal and the non-inverting output signal to output a transitional output signal;
a first inverter receiving and inverting the transitional output signal to generate a first control signal; and
a second inverter receiving and inverting the first control signal to generate a second control signal as an output signal,
wherein the first and second control signals jointly control the first and second switch devices so as to make the output signal have a minimum hysteresis center offset.

6. The current comparator according to claim 5, wherein the first switch device comprises:
a first switch receiving the non-inverting input signal and connected to the non-inverting terminal of the differential amplifier;
a second switch receiving the non-inverting input signal and connected to the inverting terminal of the differential amplifier;
a third switch receiving the inverting input signal and connected to the inverting terminal of the differential amplifier; and
a fourth switch receiving the inverting input signal and connected to the non-inverting terminal of the differential amplifier, and the second switch device comprises:
a fifth switch receiving the differential non-inverting output signal and connected to the non-inverting terminal of the comparator;
a sixth switch receiving the differential non-inverting output signal and connected to the inverting terminal of the comparator;
a seventh switch receiving the differential inverting output signal and connected to the inverting terminal of the comparator; and
an eighth switch receiving the differential inverting output signal and connected to the non-inverting terminal of the comparator,
wherein each of the first, third, fifth and seventh switches is controlled by the first control signal to be on and close, and each of the second, fourth, sixth and eighth switches is controlled by the second control signal to be on and close.

7. The current comparator according to claim 5, wherein the offset current is inherent in the differential amplifier.

8. The current comparator according to claim 5, wherein the offset current is externally applied to the differential amplifier.

9. A constant current charging device, comprising:
a voltage comparator as claimed in claim 1;
a rechargeable battery;
a charging circuit receiving a direct current (DC) power to charge the rechargeable battery to output a sense voltage,
wherein the sense voltage is sent to the inverting terminal of the differential amplifier so as to enable the voltage comparator to output a control signal to control the charging circuit to charge the rechargeable battery.

10. The constant current charging device according to claim 9, wherein the voltage comparator receives a reference signal at the non-inverting terminal of the differential amplifier.
